(19) United States
(12) Patent Application Publication
(10) Pub. No.: US 2024/0157390 A1
(43) Pub. Date: May 16, 2024

(54) SUBSTRATE PROCESSING APPARATUS AND SUBSTRATE PROCESSING METHOD

(71) Applicant: SCREEN Holdings Co., Ltd., Kyoto (JP)

(72) Inventors: Tomohiro MOTONO, Kyoto (JP); Koji ANDO, Kyoto (JP); Noritake SUMI, Kyoto (JP); Kei SUZUKI, Kyoto (JP)

(21) Appl. No.: 18/509,106

(22) Filed: Nov. 14, 2023

(30) Foreign Application Priority Data
Nov. 16, 2022 (JP) 2022-183178

(51) Int. Cl. B05C 5/02; B05D 1/26

(52) U.S. Cl. CPC B05C 5/02; B05D 1/26

(57) ABSTRACT

In the substrate processing apparatus, a support tray supporting a substrate is housed in an internal space of a chamber. A processing fluid is supplied into the internal space from one end side of the internal space. The support tray includes a tray member and a plurality of support members attached to the tray member in such a manner as to surround a substrate facing surface. The tray member has a downstream-side standing portion that has a downstream-side standing portion that stands upward further than the substrate facing surface while located in proximity to a peripheral surface of the substrate on a downstream side supported by the plurality of support members. An upper surface of the downstream-side standing portion is below the upper surface of the substrate in a vertical direction supported by the plurality of support members.

### CROSS REFERENCE TO RELATED APPLICATION

The disclosure of Japanese Patent Application No. 2022-183178 filed on Nov. 16, 2022 including specification, drawings and claims is incorporated herein by reference in its entirety.

### BACKGROUND OF THE INVENTION

### 1. Field of the Invention

The present invention relates to a substrate processing apparatus and a substrate processing method of processing a substrate with a liquid adhering to the substrate using a processing fluid in a supercritical state.

### 2. Description of the Related Art

As a result of implementation of a wet-type process on a substrate using a liquid, the liquid adheres to a surface of the substrate. After implementation of the wet-type process, the substrate is dried by a known substrate processing apparatus such as an apparatus described in Japanese Patent Application Laid-Open No. 2021-009875, for example. In this apparatus, a shallow recess is provided in a support tray having a flat plate shape. The substrate is supported horizontally in the recess in a face-up posture in which a surface of the substrate is facing upward while a tiny gap is present from an upper surface of the support tray. The support tray in this state is loaded into a processing chamber and the interior of the chamber is filled with a processing fluid in a supercritical state, thereby processing the substrate (supercritical process).

### SUMMARY OF INVENTION

A liquid forming a liquid film covering the substrate during the loading is expected to be removed from the substrate surface by being replaced with the processing fluid. In some cases, however, part of the liquid gets into a narrow gap between a lower surface of the substrate and the upper surface of the support tray. The liquid remaining in the gap, namely, a residual liquid may flow back to the surface of the substrate. This might cause a problem of re-adhesion of the residual liquid to the upper surface of the substrate.

From this viewpoint, preventing backflow of the residual liquid to the upper surface of the substrate is required in the supercritical process. In this regard, the above-described conventional technique can be said to have room for improvement.

The present invention has been made in view of the foregoing issue, and is intended to provide a substrate processing apparatus and a substrate processing method allowing prevention of a liquid from re-adhering to a substrate during removal of the liquid from the substrate using a processing fluid.

One aspect of this invention is directed to a substrate processing apparatus that processes a substrate with a liquid adhering to an upper surface of the substrate using a processing fluid in a supercritical state. The apparatus includes: a support tray including a tray member, having a substrate facing surface facing a lower surface of the substrate, and a plurality of support members attached to the tray member in such a manner as to surround the substrate facing surface, and being configured to support the substrate while separating the substrate upward from the substrate facing surface using the support members; a chamber having an internal space capable of housing the support tray supporting the substrate; and a fluid supplier configured to supply the processing fluid into the internal space from one end side of the internal space, thereby forming a laminar flow of the processing fluid flowing toward the other end side of the internal space along the upper surface of the substrate supported by the support tray, wherein with the other end side of the internal space with respect to a first virtual line defined as a downstream side, the first virtual line passing through a center of the substrate facing surface and extending in a horizontal direction perpendicular to a flow direction of the laminar flow, the tray member includes a downstream-side standing portion standing upward further than the substrate facing surface while located in proximity to a peripheral surface of the substrate on the downstream side supported by the plurality of support members, and the downstream-side standing portion has an upper surface below the upper surface of the substrate in a top-bottom direction supported by the plurality of support members.

Other aspect of the invention is a substrate processing method of processing a substrate with a liquid adhering to an upper surface of the substrate using a processing fluid in a supercritical state. The method includes: housing a support tray into internal space of a chamber, the support tray supporting the substrate while separating the substrate upward from a substrate facing surface using a plurality of support members attached to a tray member having the substrate facing surface facing a lower surface of the substrate in such a manner as to surround the substrate facing surface; supplying the processing fluid into the internal space from one end side of the internal space, thereby forming a laminar flow of the processing fluid flowing toward the other end side of the internal space along the upper surface of the substrate supported by the support tray; and discharging the liquid together with the processing fluid in the laminar flow from the upper surface of the substrate toward the other end side of the internal space, wherein with the other end side of the internal space with respect to a first virtual line defined as a downstream side, the first virtual line passing through a center of the substrate facing surface and extending in a horizontal direction perpendicular to a flow direction of the laminar flow, the discharging operation is performed through a downstream-side standing portion standing upward further than the substrate facing surface while located in proximity to a peripheral surface of the substrate on the downstream side supported by the plurality of support members, and having an upper surface below the upper surface of the substrate in a top-bottom direction supported by the plurality of support members.

According to the invention having the above-described configuration, the support tray supports the substrate while separating the substrate upward from the substrate facing surface of the support tray. Furthermore, in the support tray, the downstream-side standing portion is provided in proximity to the peripheral surface of the substrate on the downstream side. According to the present invention, the upper surface of the downstream-side standing portion is below the upper surface of the substrate supported by the support tray. Thus, on the occurrence of backflow of part of the liquid having gotten in between the lower surface of the substrate and the substrate facing surface, namely, on the occurrence of backflow of a residual liquid, the residual liquid flows toward the upper surface of the downstream-side standing portion. Thus, re-adhesion of the residual liquid to the upper surface of the substrate is prevented.

As described above, according to the present invention, the support tray is configured in such a manner that the upper surface of the downstream-side standing portion is below the upper surface of the substrate in the vertical direction. Thus, during removal of the liquid from the substrate using the processing fluid, it is possible to prevent re-adhesion of the liquid to the substrate effectively.

All of a plurality of constituent elements of each aspect of the invention described above are not essential and some of the plurality of constituent elements can be appropriately changed, deleted, replaced by other new constituent elements or have limited contents partially deleted in order to solve some or all of the aforementioned problems or to achieve some or all of effects described in this specification. Further, some or all of technical features included in one aspect of the invention described above can be combined with some or all of technical features included in another aspect of the invention described above to obtain one independent form of the invention in order to solve some or all of the aforementioned problems or to achieve some or all of the effects described in this specification.

### BRIEF DESCRIPTION OF THE DRAWINGS

FIG. 1 shows an overall configuration of a substrate processing apparatus to which the present invention is applicable.

FIG. 2A is a perspective view showing a first embodiment of the support tray.

FIG. 2B is a plan view of the support tray shown in FIG. 2A.

FIGS. 2C and 2D are a sectional view taken along a line C-C and a sectional view taken along a line D-D in FIG. 2B respectively.

FIG. 3 schematically shows the configuration of a support tray according to the conventional technique.

FIG. 4 is a perspective view showing a second embodiment of the support tray.

FIG. 5A is a plan view showing a third embodiment of the support tray.

FIG. 5B is a sectional view taken along a line B-B in FIG. 5A.

FIG. 6 is a perspective view showing a fourth embodiment of the support tray.

FIG. 7A is a plan view showing a fifth embodiment of the support tray.

FIG. 7B is a sectional view taken along a line B-B in FIG. 7A.

### DETAILED DESCRIPTION OF THE PREFERRED EMBODIMENTS

Some embodiments of a substrate processing apparatus according to the present invention will be described below. A basic apparatus configuration is common while the configuration of a support tray partially differs between the embodiments. An overall configuration of the substrate processing apparatus will be described first and then characteristic parts of the corresponding embodiments will be described individually.

### <Overall Configuration of Apparatus>

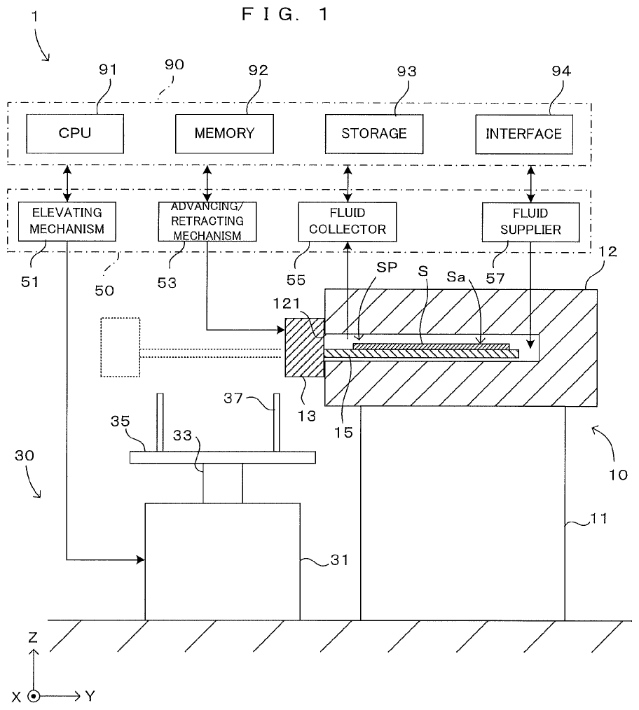

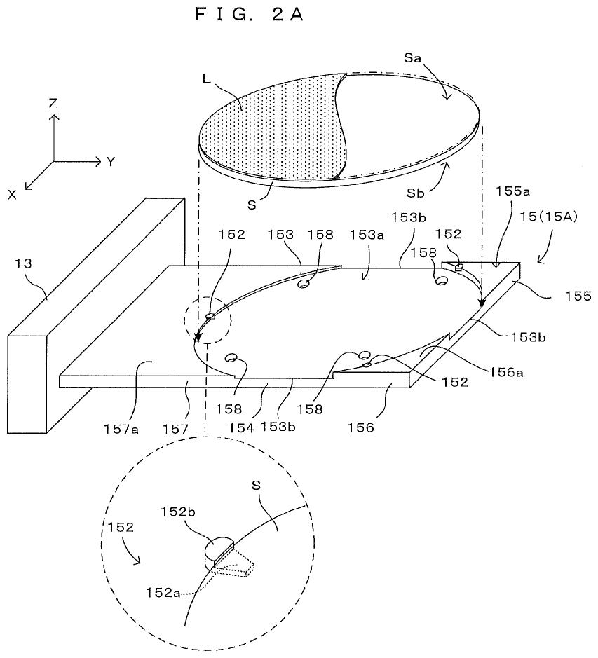

FIG. 1 shows an overall configuration of a substrate processing apparatus to which the present invention is applicable. The substrate processing apparatus 1 is an apparatus for processing an upper surface of each type of substrate such as a semiconductor substrate, for example, using a supercritical fluid. For example, the substrate processing apparatus 1 is capable of performing a supercritical drying process of drying a substrate by replacing a liquid (indicated by a sign L in FIGS. 2, 4, and 6) adhering to the substrate with a supercritical processing fluid. To show directions in a unified manner in the drawings referred to below, an XYZ orthogonal coordinate system is defined as shown in FIG. 1. An XY plane represents a horizontal plane. A Z direction represents a vertical direction. More specifically a (−Z) direction represents a vertically downward direction.

Here, various substrates such as semiconductor wafers, glass substrates for photomask, glass substrates for liquid crystal display, glass substrates for plasma display, substrates for FED (Field Emission Display), substrates for optical disk, substrates for magnetic disk, and substrates for magneto-optical disk can be adopted as the “substrate” in this embodiment. A substrate processing apparatus used to process a semiconductor wafer is mainly described as an example with reference to the drawings, but the substrate processing apparatus can be adopted also to process various substrates illustrated above. A substrate S used as an example in the following description has a circuit pattern, etc. formed only on one main surface thereof. Here, a surface corresponding to the main surface with the circuit pattern, etc. will be called a “front surface,” and a main surface on the opposite side without a circuit pattern, etc. will be called a “back surface.” Furthermore, a surface of the substrate S facing downward will be called a “lower surface,” and a surface of the substrate S facing upward will be called an “upper surface.” In the example descried below, the substrate S to be processed is in a posture in which the front surface of the substrate S is facing upward, namely, in a posture in which the front surface corresponds to the upper surface.

The substrate processing apparatus 1 includes a processing unit 10, a transfer unit 30, a supply unit 50 and a control unit 90. The processing unit 10 serves as an execution subject of a supercritical drying process. The transfer unit 30 receives an unprocessed substrate S transported by an external conveying device not shown in the figure and carries the substrate S into the processing unit 10. Further, the transfer unit 30 delivers a processed substrate S from the processing unit 10 to the external conveying device. The supply unit 50 supplies chemical substances, power, energy and the like necessary for the process to the processing unit 10 and the transfer unit 30.

The control unit 90 realizes a predetermined process by controlling these components of the apparatus. For this purpose, the control unit 90 includes a CPU 91 for executing various control programs, a memory 92 for temporarily storing processing data, a storage 93 for storing the control programs to be executed by the CPU 91, an interface 94 for information exchange with a user and an external apparatus, and the like. Operations of the apparatus to be described later are realized by the CPU 91 causing each component of the apparatus to perform a predetermined operation by executing the control program written in the storage 93 in advance.

The processing unit 10 has a structure in which a processing chamber 12 is settled on a pedestal 11. The processing chamber 12 is structured by a combination of several metal blocks which form a hollow inside serving as an internal space SP. A substrate S to be processed is carried into the internal space SP to be processed. A slit-like aperture 121 elongated in an X direction is formed in a (−Y) side surface of the processing chamber 12. The internal space SP communicates with an outside space via the aperture 121.

A lid member 13 is provided on the (−Y) side surface of the processing chamber 12 to close the aperture 121. A support tray 15 in the form of a flat plate is attached in a horizontal posture to a (+Y) side surface of the lid member 13. An upper surface 151 of the support tray 15 serves as a support surface on which the substrate S can be placed. The lid member 13 is supported horizontally movably in a Y direction by an unillustrated support mechanism.

The lid member 13 is movable toward and away from the processing chamber 12 by an advancing/retracting mechanism 53 provided in the supply unit 50. Specifically, the advancing/retracting mechanism 53 includes a linear motion mechanism such as a linear motor, a linear guide, a ball-screw mechanism, a solenoid or an air cylinder. Such a linear motion mechanism moves the lid member 13 in the Y direction. The advancing/retracting mechanism 53 operates in response to a control command from the control unit 90.

By a movement of the lid member 13 in a (−Y) direction, as shown by dotted lines in FIG. 1, the lid member 13 separates away from the processing chamber 12. If the support tray 15 is pulled out from the internal space SP to outside via the aperture 121 as shown by the dotted lines, the support tray 15 is accessible from outside. Specifically, it becomes possible to place the substrate S on the support tray 15 and take out the substrate S placed on the support tray 15. On the other hand, as shown by solid lines in FIG. 1, the lid member 13 moves in a (+Y) direction, whereby the support tray 15 is accommodated into the internal space SP. If the substrate S is placed on the support tray 15, the substrate S is carried into the internal space SP together with the support tray 15.

When the lid member 13 moves in the (+Y) direction, the opening 121 is closed to enclose the internal space SP. While not shown in the drawings, a seal member is provided between the side surface of the lid member 13 on the (+Y) side and the side surface of the processing chamber 12 on the (−Y) side to maintain an air-tight condition in the internal space SP. Furthermore, the lid member 13 is fixed to the processing chamber 12 by a lock mechanism not shown in the drawings. While the air-tight condition is ensured in this way in the internal space SP, the substrate S is processed in the internal space SP.

In the supercritical drying process mainly intended to dry a substrate while preventing pattern collapse due to surface tension of a liquid, the substrate S is loaded while an upper surface Sa of the substrate S is covered with a liquid film for the purpose of preventing pattern collapse to occur if the upper surface Sa is exposed. An organic solvent of relatively low surface tension that may be isopropyl alcohol (IPA) or acetone, for example, is used preferably as a liquid to form the liquid film.

According to the present embodiment, a fluid supplier 57 provided to the supply unit 50 supplies the processing unit 10 with a fluid of a substance available for the supercritical process in a gas or liquid form that may be carbon dioxide, for example. Carbon dioxide is a chemical substance suitable for the supercritical drying process in that it has a property of being brought to a supercritical state in a relatively low temperature and a relatively low pressure and dissolving an organic solvent well used frequently in a substrate process.

When the fluid is filled in the internal space SP and a temperature and a pressure in the internal space SP reach appropriate levels, the fluid is brought to a supercritical state. By doing so, the substrate S is processed with the supercritical fluid in the processing chamber 12. The supply unit 50 is provided with a fluid collector 55 and the fluid after being used for the process is collected by the fluid collector 55. The fluid supplier 57 and the fluid collector 55 are controlled by the control unit 90.

The transfer unit 30 is responsible for transfer of the substrate S between the external transport device and the support tray 15. For this purpose, the transfer unit 30 includes a body 31, an elevating member 33, a base member 35, and a plurality of lift pins 37. The elevating member 33 is a columnar member extending in the Z direction and is supported movably in the Z direction by the body 31.

A base member 35 having a substantially horizontal upper surface is mounted on the top of the elevating member 33. The lift pins 37 are provided upward in standing positions from the upper surface of the base member 35. Each of the lift pins 37 has an upper end to abut on the lower surface of the substrate S, thereby supporting the substrate S from below in a horizontal posture. To support the substrate S stably, it is desirable to provide three or more lift pins 37 having upper ends of heights equal to each other.

The elevating member 33 can be moved up and down under control by an up-and-down controller 51 provided to the supply unit 50. More specifically, the body 31 of the transfer unit 30 is provided with a linear motion mechanism (not shown in the drawings) such as a liner motor, a linear motion guide, a ball screw mechanism, a solenoid, or an air cylinder, for example, and such a linear motion mechanism moves the elevating member 33 in the Z direction under control by the up-and-down controller 51. The up-and-down controller 51 operates in response to a control command from the control unit 90.

The base member 35 is moved up and down by upward and downward movements of the elevating member 33, and the plurality of lift pins 37 move up and down integrally with the base member 35. In this way, the transfer of the substrate S is realized between the transfer unit 30 and the support tray 15. The specifics are as follows.

As described later, the support tray 15 is provided with a through hole corresponding to each of the lift pins 37 of the transfer unit 30. Specifically, the through hole is formed at a position to become directly above each of the lift pins 37 when the support tray 15 is pulled out of the processing chamber 12. When the elevating member 33 moves up and down to move up the base member 35, each of the lift pins 37 passes through the through hole at the support tray 15 to reach a position where a tip of the lift pin 37 is above an upper surface of the support tray 15. In this state, the unprocessed substrate S, having been transported by an external carrier such as a transport robot having a hand capable of holding a substrate, for example, is transferred to the lift pins 37.

In response to the downward movement of the lift pins 37 holding the substrate S, the substrate S also moves down. Then, the lift pins 37 move down further while the substrate S contacts the upper surface of the support tray 15. By doing so, the substrate S is transferred from the lift pins 37 to the support tray 15 and becomes supported by the support tray 15. In this way, the substrate S is loaded into the substrate processing apparatus 1. The lift pins 37 finally go down to positions where the lift pins 37 do not interfere with the motion of opening and closing the lid member 13.

The substrate S can be unloaded from the substrate processing apparatus 1 through a procedure reverse to that described above. Specifically, the lift pins 37 move up while the substrate S is supported by the support tray 15 to raise the substrate S. This generates space between the lower surface of the substrate S and the upper surface of the support tray 15 and the hand of the transport robot is introduced into this space. By doing so, the substrate S can be transferred from the lift pins 37 to the transport robot.

As described above, the supercritical drying process is performed on the substrate S in the substrate processing apparatus 1. A sequential flow of this process is as follows. First, the substrate S with the upper surface Sa covered with a film of a liquid is loaded from outside and placed on the support tray 15. The support tray 15 enters the internal space SP of the processing chamber 12, thereby housing the substrate S into the internal space SP (housing step). Then, with the internal space SP closed by the lid member 13, a processing fluid in a gas or liquid form is supplied from the fluid supplier 57 to the internal space SP (supplying step). The processing fluid flows along the upper surface Sa of the substrate S supported by the support tray 15 from a (+Y) direction side toward a (−Y) direction side. The processing fluid in such a laminar flow is pressurized in the internal space SP to be brought to a supercritical state. By doing so, the liquid on the substrate S is replaced with the supercritical processing fluid. Supply of the processing fluid from the fluid supplier 57 and discharge of the processing fluid by the fluid collector 55 are continued for a certain period of time, thereby discharging the liquid coming off the substrate S (discharging step). Finally, the processing fluid makes a phase transition from a supercritical state to a gas phase without intervention of a liquid phase and is discharged, thereby bringing the substrate S to a dry state.

The following describes some embodiments of the support tray 15 (support trays 15A to 15E) in the substrate processing apparatus 1 described above. The configuration of the support tray 15 partially differs between the embodiments but the support tray 15 is otherwise common between the embodiments and operates in the manner described above. In the following descriptions of the embodiments, structures having a common configuration or function will be given the same sign or corresponding signs, and these structures will not be described repeatedly. Furthermore, regarding structures shown in a plurality of drawings and having association clearly understandable from the drawings, insertion of signs may be omitted in some of the drawings.

### FIRST EMBODIMENT

FIG. 2A is a perspective view showing a first embodiment of the support tray. FIG. 2B is a plan view of the support tray shown in FIG. 2A. FIGS. 2C and 2D are a sectional view taken along a line C-C and a sectional view taken along a line D-D in FIG. 2B respectively. The support tray 15A of the first embodiment includes a tray member 151 and a plurality of support pins 152. The tray member 151 has a configuration where a recess 153 having a size conforming to the planar size of the substrate S, specifically, having a diameter slightly larger than the diameter of the circular substrate S is formed at a horizontal and planar upper surface of a structure of a flat plate shape, for example. The recess 153 has a bottom surface 153a formed into a horizontal surface and corresponding to an example of a “substrate facing surface” of the present invention.

The recess 153 partially extends as far as to a side surface 154 of the tray member 151. Specifically, the recess 153 has a side wall surface that is not a circular shape but is partially cut out. This forms cutout portions 153b where the bottom surface 153a of the recess 153 partially connects to the side surface 154 directly. In this example, the cutout portions 153b are formed at both end portions of the support tray 15A on the X side and at an end portion of the support tray 15A on the (+Y) side, and the bottom surface 153a directly connects to the side surface 154 at these portions. The presence of the cutout portions 153b provides three standing portions 155 to 157 at the tray member 151. The tray member 151 is a base plate having a flat plate shape, and the standing portions 155 to 157 are plates having flat plate shapes mounted on or formed integrally with the tray member (base plate) 151. The particular configurations and functions thereof will be described later in detail.

A through hole 158 as a passage for the lift pin 37 of the transfer unit 30 is formed at a position of the bottom surface 153a corresponding to the lift pin 37. The lift pin 37 moves up and down through the through hole 158, thereby realizing a state where the substrate S is housed in the recess 153 and a state where the substrate S is raised upward from the recess 153.

The recess 153 has a peripheral edge where the support pins 152 are arranged. While the number of the support pins 152 is determined freely, it is desirably equal to or greater than 3 from the viewpoint of supporting the substrate S stably. In the present embodiment, three support pins 152 are attached to corresponding ones of the standing portions 155 to 157 in such a manner as to surround the bottom surface 153a in a plan view from above. As shown in a partially enlarged view in FIG. 2A, the support pins 152 each have a height regulator 152a and a horizontal position regulator 152b.

The height regulator 152a has a planar upper surface. By abutting on a peripheral edge of a lower surface Sb of the substrate S, the height regulator 152a supports the substrate S and regulates the position of the substrate S in the vertical direction Z (this position will be called a “height position”). The horizontal position regulator 152b extends upward further than an upper end of the height regulator 152a. By abutting on a side surface of the substrate S, the horizontal position regulator 152b regulates the position of the substrate S in a horizontal direction (XY direction). As shown in FIGS. 2C and 2D, by the provision of the support pins 152, the substrate S is supported in a horizontal posture separated upward from the bottom surface 153a of the recess 153 while facing the bottom surface 153a. As shown in FIGS. 2C and 2D, the upper surface Sa of the substrate S supported in this way is located at a height position H1.

The configurations and functions of the standing portions 155 to 157 will be described next by referring to FIGS. 2A to 2D. As shown in FIG. 2B, to clearly show the positions of the standing portions 155 to 157 relative to each other, a first virtual line VL1 and a second virtual line VL2 are defined in the present specification. Specifically, the first virtual line VL1 means a line passing through a center 153c of the bottom surface 153a and extending in the horizontal direction X perpendicular to a flow direction Y of a laminar flow of a processing fluid. The second virtual line VL2 means a line passing through the center 153c of the bottom surface 153a and extending parallel to the flow direction Y.

The standing portions 155 and 156 are both located on the (+Y) direction side of the internal space SP with respect to the first virtual line VL1 and are located separately on a (−X) direction side and on a (+X) direction side respectively with respect to the second virtual line VL2. The standing portions 155 and 156 are provided in proximity to a peripheral surface of the substrate S in such a manner that respective upper surfaces 155a and 156a of the standing portions 155 and 156 are both aligned with the height position H1 of the upper surface Sa of the substrate S supported by the support pins 152 in the vertical direction Z. Thus, when a processing fluid flows to the upper surface Sa of the substrate S after passing through the upper surfaces 155a and 156a of the standing portions 155 and 156, no disturbance is caused in a laminar flow formed by the processing fluid so a liquid L on the substrate S is replaced efficiently with the supercritical processing fluid. In the present specification, as viewed in the flow direction Y of the processing fluid, the (+Y) direction side and the (−Y) direction side of the internal space SP with respect to the first virtual line VL1 are called “upstream” and “downstream” respectively.

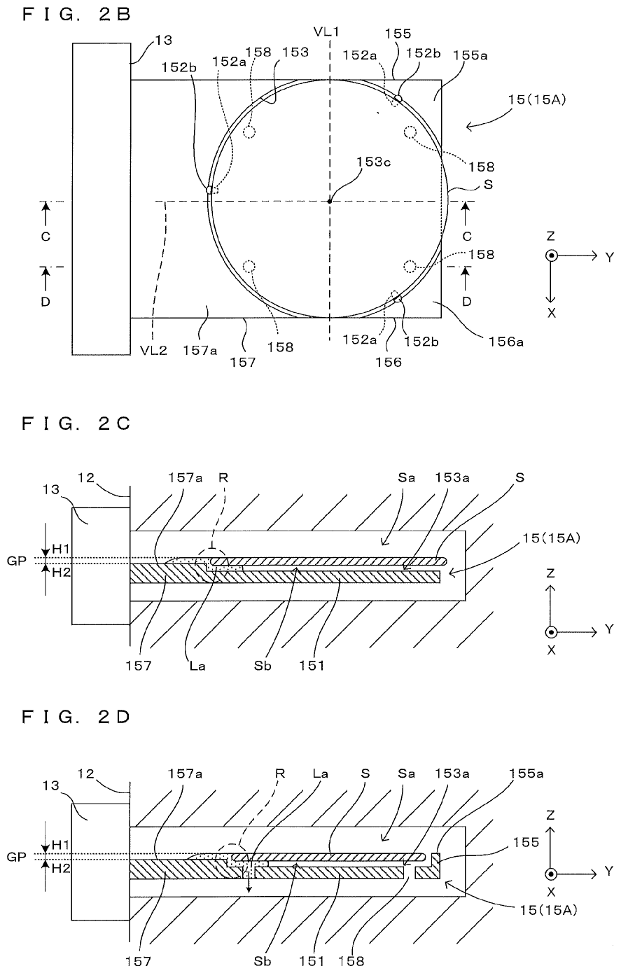

Meanwhile, the standing portion 157 is located on the (−Y) direction side of the internal space SP, namely, on the downstream side with respect to the first virtual line VL1. The standing portion 157 is provided in proximity to the peripheral surface of the substrate S in such a manner that an upper surface 157a of the standing portion 157 is located at a position H2 below the height position H1 of the upper surface Sa of the substrate S in the vertical direction Z supported by the support pins 152. Specifically, as shown in FIGS. 2C and 2D, the upper surface 157a of the standing portion 157 is below the upper surface Sa of the substrate S by a gap GP. This achieves operation and effect as follows. Here, the operation and effect will be described by making comparison to a conventional example shown in FIG. 3 having a configuration where the upper surface 157a of the standing portion 157 is aligned with the upper surface Sa of the substrate S like in the conventional technique.

FIG. 3 schematically shows the configuration of a support tray according to the conventional technique. According to the conventional technique shown in FIG. 3, a standing portion 159 corresponding to the standing portion 157 of the first embodiment is provided in proximity to the peripheral surface of the substrate S in such a manner as to be aligned with the height position H1 of the upper surface Sa of the substrate S supported by the support pins 152. Hence, as the upper surface Sa of the substrate S and an upper surface 159a of the standing portion 159 are at the same height in the vertical direction Z, the occurrence of backflow of a residual liquid La having gotten into a narrow gap between the lower surface Sb of the substrate S and the bottom surface 153a of the support tray 15 and remaining therein may cause re-adhesion of part of the residual liquid La to the upper surface Sa of the substrate S.

In response to this, according to the first embodiment, the upper surface 157a of the standing portion 157 is below the upper surface Sa of the substrate S, as shown in FIGS. 2C and 2D. Thus, the residual liquid La having flowed back reaches the upper surface 157a of the standing portion 157, thereby preventing backflow of the residual liquid La to the substrate S effectively. As a result, it becomes possible to dry the substrate S favorably in the substrate processing apparatus 1.

As shown in FIGS. 2C and 2D, to achieve the foregoing effect of preventing backflow effectively, it is preferable that the gap GP (=H1−H2) in the vertical direction Z between the upper surface 157a of the standing portion 157 and the upper surface Sa of the substrate S be equal to or greater than 0.5 mm in an adjoining region R where the standing portion 157 and the substrate S supported by the support pins 152 adjoin each other.

Meanwhile, the inventors of the present application have knowledge that the gap GP exceeding 1.0 mm increases a likelihood of a disturbed flow of a processing fluid in the adjoining region R, so that the efficiency of replacement of the liquid L with the supercritical processing fluid may be reduced in the adjoining region R. Thus, it is preferable that the gap GP be set equal to or greater than 0.5 mm and equal to or less than 1.0 mm.

As described above, according to the first embodiment, the support pin 152 corresponds to an example of a “support member” of the present invention. The (+Y) direction side and the (−Y) direction side of the internal space SP correspond to “one end side of internal space” and “the other end side of the internal space” of the present invention respectively. The standing portions 155 and 156 each correspond to an example of an “upstream-side standing portion” of the present invention. The standing portion 157 corresponds to an example of a “downstream-side standing portion” of the present invention.

### SECOND EMBODIMENT

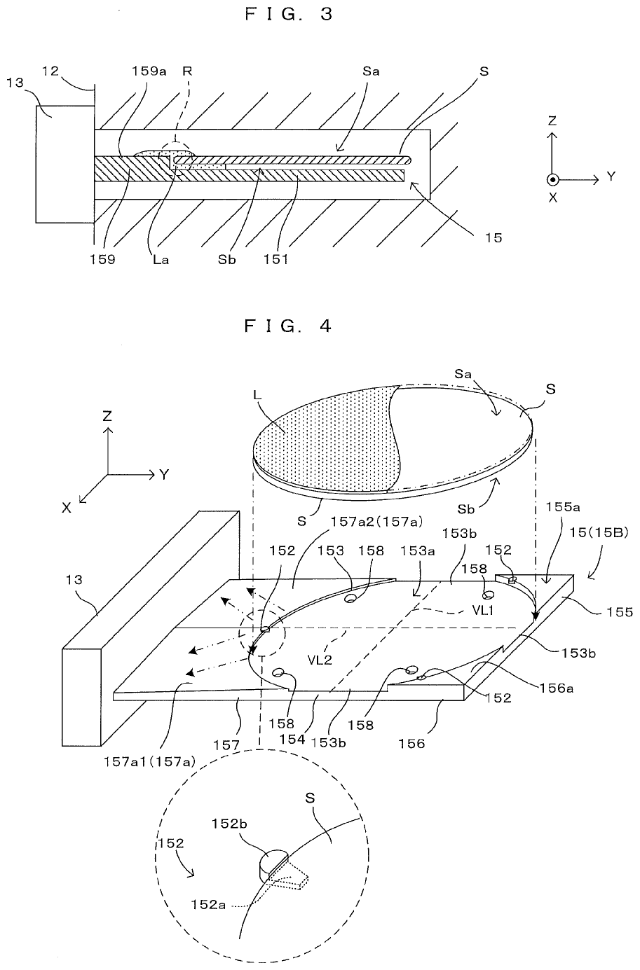

FIG. 4 is a perspective view showing a second embodiment of the support tray. The second embodiment largely differs from the first embodiment in the shape of the upper surface 157a of the standing portion 157. Specifically, in the support tray 15A of the first embodiment, the upper surface 157a is a single horizontal surface having the height position H2 in any region. By contrast, in the support tray 15B of the second embodiment, the upper surface 157a is composed of an inclined surface. While this inclined surface is at the height position H2 in the adjoining region R like in the first embodiment, the inclined surface becomes lower in height as the inclined surface extends further in the flow direction Y of a processing fluid, namely, as the included surface extends further from the (+Y) direction side toward the (−Y) direction side. Furthermore, with the (+X) direction side and the (−X) direction side of the first virtual line VL1 with respect to the second virtual line VL2 defined as a left side and a right side respectively, the upper surface 157a of the standing portion 157 has a left-side inclined region 157a1 that becomes lower in height as the left-side inclined region 157a1 extends further from the second virtual line VL2 toward the left side and a right-side inclined region 157a2 that becomes lower in height as the right-side inclined region 157a2 extends further from the second virtual line VL2 toward the right side. This allows the residual liquid La having flowed back (see FIGS. 2C and 2D) and certainly the processing fluid having passed through the upper surface Sa of the substrate S to be discharged efficiently from an end surface on the (+X) side and an end surface on the (−X) side of the support tray 15 while flowing the residual liquid La and the processing fluid to the right and to the left separately, as indicated by two-dot chain lines in FIG. 4. As a result, it becomes possible to prevent the residual liquid La from flowing back to the substrate S more effectively than in the first embodiment.

### THIRD EMBODIMENT

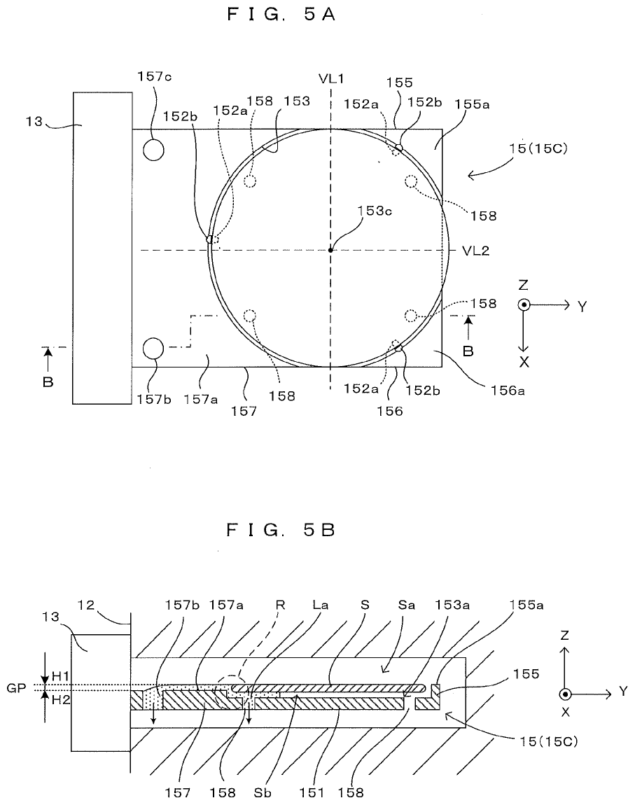

FIG. 5A is a plan view showing a third embodiment of the support tray. FIG. 5B is a sectional view taken along a line B-B in FIG. 5A. The support tray 15C of the third embodiment largely differs from the support tray 15A of the first embodiment in that it additionally includes a through hole 157b and a through hole 157c penetrating an end portion of the standing portion 157 on the (−Y) side in the vertical direction Z. The one through hole 157b is provided on the left side with respect to the second virtual line VL2, namely, on the (+X) direction side. The other through hole 157c is provided on the right side with respect to the second virtual line VL2, namely, on the (−X) direction side. This allows the residual liquid La having flowed back (see FIGS. 2C and 2D) and certainly a processing fluid having passed through the upper surface Sa of the substrate S to be discharged efficiently through the through hole 157b, as shown in FIG. 5B. Like the through hole 157b, the through hole 157c is also used for discharging the processing fluid and the residual liquid La. As a result, it becomes possible to prevent the residual liquid La from flowing back to the substrate S more effectively than in the first embodiment.

According to the third embodiment, each of the through holes 157b and 157c corresponds to an example of a “downstream-side through hole” of the present invention, the through hole 157b on the (+X) direction side with respect to the second virtual line VL2 corresponds to a “left-side through hole,” and the through hole 157c on the (−X) direction side with respect to the second virtual line VL2 corresponds to a “right-side through hole.”

### FOURTH EMBODIMENT

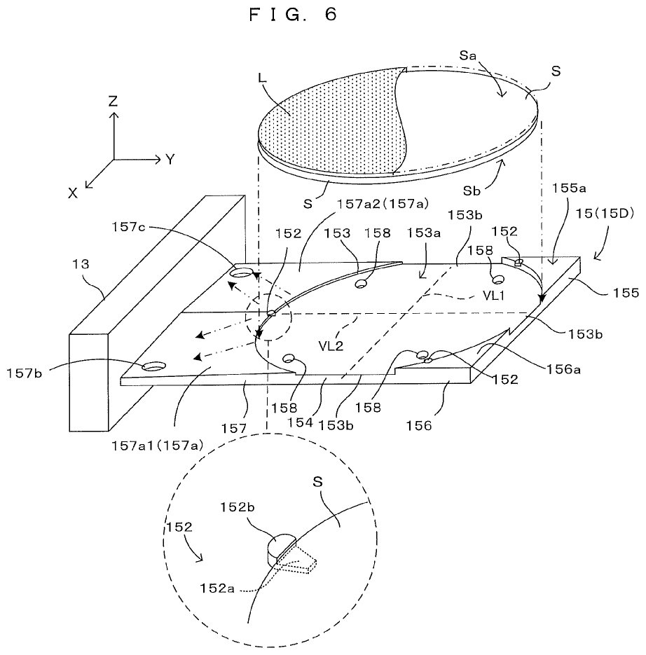

FIG. 6 is a perspective view showing a fourth embodiment of the support tray. In comparison to the support tray 15A of the first embodiment, the support tray 15D of the fourth embodiment additionally includes the inclined surface structure employed in the second embodiment and the downstream-side through hole employed in the third embodiment. As shown in FIG. 6, in the support tray 15D of the fourth embodiment, a part of the left-side inclined region 157a1 on the (+X) direction side and on the (−Y) direction side (this part will be called a “left-side low part”) is a lowermost part in the vertical direction Z, and the left-side through hole 157b is provided in this part. Furthermore, a part of the right-side inclined region 157a2 on the (−X) direction side and on the (−Y) direction side (this part will be called a “right-side low part”) is a lowermost part in the vertical direction Z, and the right-side through hole 157c is provided in this part. A processing fluid and the residual liquid La having flowed into the adjoining region R travel along the upper surface 157a of the standing portion 157 and are collected at the left-side low part and the right-side low part, and then discharged downward from the support tray 15 through the through holes 157b and 157c. As a result, it becomes possible to prevent the residual liquid La from flowing back to the substrate S more effectively than in the first to third embodiments.

### FIFTH EMBODIMENT

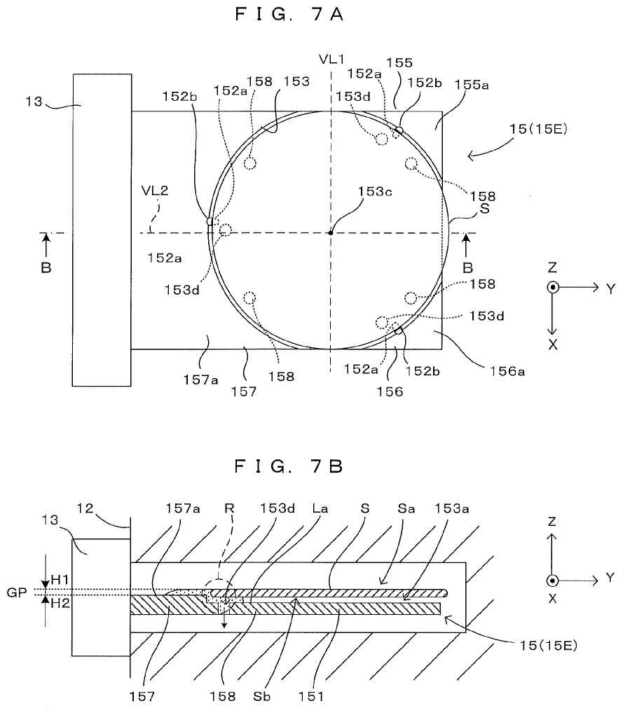

FIG. 7A is a plan view showing a fifth embodiment of the support tray. FIG. 7B is a sectional view taken along a line B-B in FIG. 7A. The support tray 15E of the fifth embodiment largely differs from the support tray 15A of the first embodiment in that it additionally includes a through hole 153d provided in the adjoining region R and penetrating the bottom surface 153a in the vertical direction Z. The bottom surface 153a corresponds to the “substrate facing surface” of the present invention, and the through hole 158 (FIG. 7A) as a passage for the lift pin 37 is provided in a part of the bottom surface 153a. Thus, the residual liquid La is partially discharged downward from the support tray 15E through the through hole 158. While this liquid discharging mechanism is also provided in the conventional technique (FIG. 3), the through hole 153d further functions as a liquid discharging mechanism as well as the through hole 158 according to the fifth embodiment. Thus, in comparison to the conventional technique, the additional provision of the through hole 153d realizes corresponding reduction in the amount of the residual liquid La to flow back. As a result, it becomes possible to prevent the residual liquid La from flowing back to the substrate S more effectively than in the first embodiment. This effect is enhanced, preferably by providing the through hole 153d corresponding to an example of a “substrate facing side through hole” of the present invention at a position closer to the standing portion 157 than the through hole 158.

Note that the invention is not limited to the embodiments described above and various changes other than the aforementioned ones can be made without departing from the gist of the invention. For example, the substrate facing side through hole 153d employed in the fifth embodiment may be added to the second to fourth embodiments.

In each of the above-described embodiments, the substrate S is supported while separated from the bottom surface 153a of the support tray 15 using the support pins 152. Instead of provision of the support pins 152, a protrusion may be provided at the bottom surface 153a for supporting the substrate. In this case, this protrusion corresponds to the “support member” of the present invention.

In the above-described embodiments, the through hole 158 as a passage for the lift pin 37 is provided at the support tray 15. However, the present invention is applicable to a substrate processing apparatus without such a through hole for up-down movement of a lift pin.

While various types of chemical substances such as IPA and carbon dioxide, for example, are given in the above-described embodiments as representative examples of available substances, they do not mean that a subject of application of the present invention is limited to a technique using such substances.

Although the invention has been described by way of the specific embodiments above, this description is not intended to be interpreted in a limited sense. By referring to the description of the invention, various modifications of the disclosed embodiments will become apparent to a person skilled in this art similarly to other embodiments of the invention. Hence, appended claims are thought to include these modifications and embodiments without departing from the true scope of the invention.

The present invention is applicable to every type of substrate processing technique of processing a substrate with a liquid adhering to a surface of the substrate using a processing fluid in a supercritical state.

What is claimed is:

1. A substrate processing apparatus that processes a substrate with a liquid adhering to an upper surface of the substrate using a processing fluid in a supercritical state, the apparatus comprising:
a support tray including a tray member, having a substrate facing surface facing a lower surface of the substrate, and a plurality of support members attached to the tray member in such a manner as to surround the substrate facing surface, and being configured to support the substrate while separating the substrate upward from the substrate facing surface using the support members;
a chamber having an internal space capable of housing the support tray supporting the substrate; and
a fluid supplier configured to supply the processing fluid into the internal space from one end side of the internal space, thereby forming a laminar flow of the processing fluid flowing toward the other end side of the internal space along the upper surface of the substrate supported by the support tray, wherein
with the other end side of the internal space with respect to a first virtual line defined as a downstream side, the first virtual line passing through a center of the substrate facing surface and extending in a horizontal direction perpendicular to a flow direction of the laminar flow,
the tray member includes a downstream-side standing portion standing upward further than the substrate facing surface while located in proximity to a peripheral surface of the substrate on the downstream side supported by the plurality of support members, and
the downstream-side standing portion has an upper surface below the upper surface of the substrate in a vertical direction supported by the plurality of support members.

2. The substrate processing apparatus according to claim 1, wherein
the upper surface of the downstream-side standing portion is an inclined surface that becomes lower in height as the inclined surface extends further in the flow direction.

3. The substrate processing apparatus according to claim 2, wherein
with one side and the other side of the first virtual line with respect to a second virtual line defined as a left side and a right side respectively, the second virtual line passing through the center of the substrate facing surface and extending parallel to the flow direction,
the inclined surface has a left-side inclined region and a right-side inclined region, the left-side inclined region becoming lower in height as the left-side inclined region extends further from the second virtual line toward the left side, the right-side inclined region becoming lower in height as the right-side inclined region extends further from the second virtual line toward the right side.

4. The substrate processing apparatus according to claim 3, wherein
a left-side through hole is provided through a lowermost part of the left-side inclined region in the vertical direction, and
a right-side through hole is provided through a lowermost part of the right-side inclined region in the vertical direction.

5. The substrate processing apparatus according to claim 1, wherein
a downstream-side through hole is provided through the downstream-side standing portion in the vertical direction.

6. The substrate processing apparatus according to claim 1, wherein
a substrate facing side through hole is provided through a region of the tray member in the vertical direction, the region being in the substrate facing surface and in proximity to the downstream-side standing portion.

7. The substrate processing apparatus according to claim 1, wherein
a gap in the vertical direction between the upper surface of the downstream-side standing portion and the upper surface of the substrate supported by the plurality of support members is equal to or greater than 0.5 mm.

8. The substrate processing apparatus according to claim 7, wherein
in an adjoining region where the downstream-side standing portion and the substrate supported by the plurality of support members adjoin each other, the gap in the vertical direction between the upper surface of the downstream-side standing portion and the upper surface of the substrate supported by the plurality of support members is equal to or less than 1.0 mm.

9. The substrate processing apparatus according to claim 1, wherein
with the one end side of the internal space with respect to the first virtual line defined as an upstream side,
the tray member includes an upstream-side standing portion standing upward further than the substrate facing surface while located in proximity to a peripheral surface of the substrate on the upstream side supported by the plurality of support members, and
the upstream-side standing portion has an upper surface at the same height as the upper surface of the substrate in the vertical direction supported by the plurality of support members.

10. A substrate processing method of processing a substrate with a liquid adhering to an upper surface of the substrate using a processing fluid in a supercritical state, the method comprising:
housing a support tray into internal space of a chamber, the support tray supporting the substrate while separating the substrate upward from a substrate facing surface using a plurality of support members attached to a tray member having the substrate facing surface facing a lower surface of the substrate in such a manner as to surround the substrate facing surface;
supplying the processing fluid into the internal space from one end side of the internal space, thereby forming a laminar flow of the processing fluid flowing toward the other end side of the internal space along the upper surface of the substrate supported by the support tray; and
discharging the liquid together with the processing fluid in the laminar flow from the upper surface of the substrate toward the other end side of the internal space, wherein
with the other end side of the internal space with respect to a first virtual line defined as a downstream side, the first virtual line passing through a center of the substrate facing surface and extending in a horizontal direction perpendicular to a flow direction of the laminar flow,
the discharging operation is performed through a downstream-side standing portion standing upward further than the substrate facing surface while located in proximity to a peripheral surface of the substrate on the downstream side supported by the plurality of support members, and having an upper surface below the upper surface of the substrate in a vertical direction supported by the plurality of support members.
